(19) United States
(12) Patent Application Publication
(10) Pub. No.: US 2011/0266670 A1
(43) Pub. Date: Nov. 3, 2011

(54) WAFER LEVEL CHIP SCALE PACKAGE WITH ANNULAR REINFORCEMENT STRUCTURE

(76) Inventors: Luke England, Portland, ME (US); Matt Ring, Saco, ME (US)

(21) Appl. No.: 12/771,857

(22) Filed: Apr. 30, 2010

(51) Int. Cl. H01L 23/488

(52) U.S. Cl. 257/738; 257/E23.023; 257/773

(57) ABSTRACT

Annular reinforcement structures that can be used in wafer level chip scale packages (WLCSP) are described. The WLCSP comprises a substrate with an IC device and a bond pad connected to the IC device, a passivation layer protecting an outer portion of the bond pad, an annular ring structure formed on an inner portion of the bond pad, an under bump metal (UBM) layer covering the annular ring structure, and a solder ball attached to the UBM layer. The annular ring structure contains a substantially planar top with vertical or non-vertical sidewalls that slope down to the inner portion of the bond pad. The annular ring structure can slow the solder crack propagation in the solder ball and therefore increase the solder joint reliability in the WLCSP. As well, the annular ring structure can increase the surface area for solder attachment to the UBM layer, improving overall ball shear strength are described. Other embodiments are described.

### FIELD

This application relates generally to semiconductor devices and methods for making such devices. More specifically, this application relates to annular reinforcement structures that can be used in wafer level chip scale semiconductor packages and methods for making and using the same.

### BACKGROUND

Semiconductor devices containing integrated circuits (ICs) are used in a wide variety of electronic apparatus. The IC devices (or chips) comprise a miniaturized electronic circuit that has been manufactured on the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices can be fabricated in a layer-by-layer process that uses a combination of many steps, including imaging, deposition, etching, doping and cleaning. One of the latter steps in the semiconductor fabrication process forms the packaging that is used to protect the IC from environmental hazards.

One type of packaging that has been recently used is wafer-level chip scale packages (WLCSP). To fabricate a WLCSP device, the equipment and processes that are used for the wafer fabrication process can also be used to complete the package assembly process. This method is easier than packaging processes that use die bonding, wire bonding, and molding. WLCSP therefore can allow manufacture of the WLCSP as a final product at the wafer level without the need to divide them into individual chips. Therefore, WLCSP devices can be manufactured at a more effective cost.

### SUMMARY

This application relates to annular reinforcement structures that can be used in wafer level chip scale packages (WLCSP). The WLCSP comprises a substrate with an IC device and a bond pad connected to the IC device, a passivation layer protecting an outer portion of the bond pad, an annular ring structure formed on an inner portion of the bond pad, an under bump metal (UBM) layer covering the annular ring structure, and a solder ball attached to the UBM layer. In some configurations, the annular ring structure contains a substantially planar top smaller in diameter than the bottom and non-vertical sidewalls that slope down to the inner portion of the bond pad. In other configurations, the annular ring structure contains vertical sidewalls with the top and bottom planes being of equal sizes. The annular ring structure can slow the solder crack propagation in the solder ball and therefore increase the solder joint reliability in the WLCSP. The annular ring structure can increase the surface area for solder attachment to the UBM layer, also improving overall ball shear strength.

### BRIEF DESCRIPTION OF THE DRAWINGS

The following description can be better understood in light of the Figures, in which:

FIG. 1 shows some embodiments of methods for forming a WLCSP device containing a polymer dielectric layer;

FIG. 2 depicts some embodiments of methods for forming a WLCSP device containing a polymer dielectric layer and an under bump metal (UBM) layer;

FIG. 3 shows some embodiments of methods for forming a WLCSP device containing an annular reinforcement structure that is higher than the surrounding polymer dielectric layer;

FIG. 4 shows some embodiments of methods for forming a WLCSP device containing the annular reinforcement structure of FIG. 3 in more detail;

FIG. 5 shows other embodiments of methods for forming a WLCSP device containing an annular reinforcement structure that is the same height as the surrounding dielectric layer;

FIG. 6 shows yet other embodiments of methods for forming a WLCSP device containing an annular reinforcement structure that is higher than the surrounding polymer dielectric and that is formed using a two-step deposition process;

FIG. 7 shows even other embodiments of methods for forming a WLCSP device containing an annular reinforcement structure that contains no surrounding polymer dielectric layer;

FIG. 8 depicts some embodiments of methods for forming a WLCSP device containing an annular reinforcement structure where the halting of solder crack progression is illustrated;

FIG. 9 shows some embodiments of methods for forming a WLCSP device containing an annular reinforcement structure on a bond pad redistribution layer;

FIG. 10 shows some embodiments of methods for forming a WLCSP device containing multiple annular reinforcement structures;

FIG. 11 shows some embodiments of the shapes that can be used for the reinforcement structures; and

FIG. 12 shows some embodiments of methods for forming a WLCSP device containing annular reinforcement structures with substantially vertical sidewalls.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the devices and associated methods of making and using the devices can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on methods for making for semiconductor devices in the IC industry, it could be modified for other devices where wafer-level packaging is needed, i.e., discrete devices, MEMS devices, LCD displays, or optoelectronics.

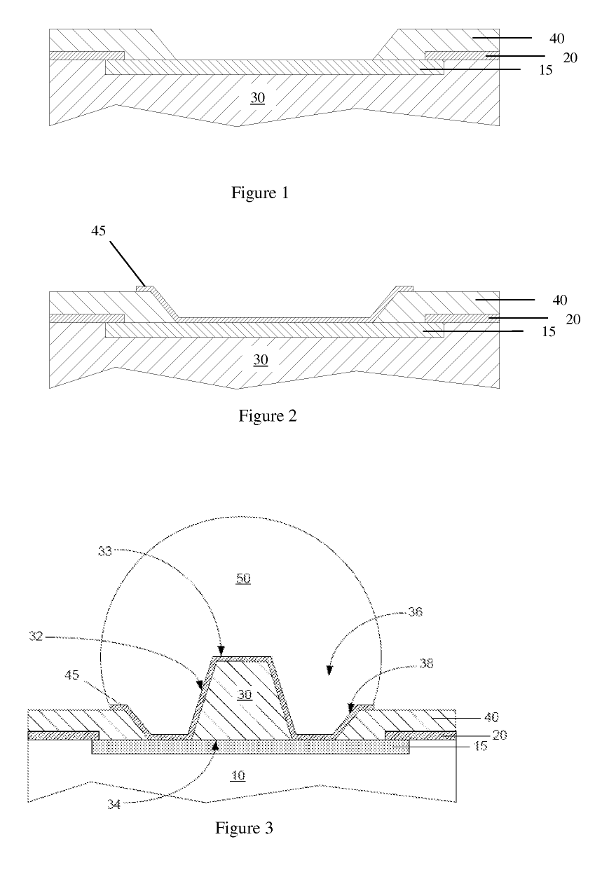

Some embodiments of the semiconductor devices and methods for making such devices are shown in the Figures. In these embodiments, the methods for making the semiconductor devices begin by providing a substrate 10 (or wafer), as shown in FIG. 1. The substrate 10 may be made of any known semiconductor material. Some non-limiting examples of such materials may include silicon, gallium arsenide, silicon carbide, gallium nitride, silicon and germanium, and combinations thereof. In some embodiments, the substrate 10 comprises a silicon wafer with an epitaxial layer of Si deposited thereon. The silicon wafer and/or the epitaxial layer can be undoped or doped with any known dopant, including boron (B), phosphorous (P), and arsenic (As).

Next, as known in the art, any known integrated circuit (IC) device can be formed on the substrate 10 using any known processing. Some non-limiting examples of these IC devices may include logic or digital IC devices, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), insulated-gate field-effect transistors (“IGFET”), memory (RAM) or processors. In some embodiments, the IC device comprises a trench MOSFET device that can be made using any process known in the art.

Next, a plurality of bond pads (or chip pads) 15 can be formed on an upper surface of the substrate 10 using any process known in the art. In some embodiments, the material for the chip pad 15 is blanket deposited and the portions of the material not needed for the chip pad 15 are removed by etching. The chip pad 15 can be made of any conductive material, such as metals and metal alloys like Al or Cu. In some embodiments, the chip pad 15 comprises aluminum or an aluminum alloy like Al—Cu, Al—Si, or Al—Si—Cu. In other embodiments, the chip pad 15 comprises Cu. The chip pads 15 can be formed so that they are electrically connected to the IC device in the substrate 10. The chip pads 15 can be disposed along the periphery of the substrate 10 or they may be formed on a central portion of the substrate 10, as shown in FIG. 1.

Next, a passivation layer 20 is formed to cover the upper surface of the substrate 10. The passivation layer 20 can be made of any known dielectric material including silicon oxide, silicon nitride, or silicon oxynitride. The passivation layer 20 can be formed by any known process, including chemical vapor deposition (CVD) or physical vapor deposition (PVD). As shown in FIG. 1, the passivation layer 20 surrounds the chip pads 15 so as to protect the IC device from external environments.

Then, as shown in FIG. 1, a dielectric layer 40 can be formed on the passivation layer 20 and on the chip pad 15. The dielectric layer 40 serves as an electrically insulating layer for formation of a metal layer on the passivation layer 20, as well as a stress relief layer. The dielectric layer 40 can be formed to any thickness on the passivation layer 20 that will provide sufficient structure for the reinforcement structures, as described herein. In some embodiments, the thickness of dielectric layer can range from about 1 μm to about 15 μm. In other embodiments, the thickness of dielectric layer can range from about 1 μm to about 5 μm. The dielectric layer 40 may comprise any organic dielectric materials which are electrically insulating. In some embodiments, the dielectric layer comprises a polymeric dielectric material such as polyimide (PI), benzocyclobutene (BCB), polybenzoxazole (PBO), or similar materials. In some configurations, the dielectric layer 40 can comprise multiple layers of these materials. The dielectric layer 40 can be made using any process known in the art, such as spin coating or screen printing.

Next, an annular reinforcement structure 30 can be formed using a polymer dielectric material. The annular ring structure 30 may or may not be the same dielectric material as the polymer dielectric material 40. In some embodiments, the annular reinforcement structure 30 comprises the same material as the polymer dielectric layer 40. In other embodiments, the annular reinforcement structure 30 comprises a different dielectric material than the polymer dielectric layer 40. The annular reinforcement structure 30 can be used to decrease or halt crack propagation in the solder ball. The annular reinforcement structure 30 can also be used to increase the contact area between the bond pad 15 and the later-formed solder ball, thus improving the connection reliability between the solder ball and the bond pad. In some embodiments, the reinforcement structure 30 comprises an annular ring as depicted in FIGS. 3 (and 4). In other embodiments, though, the reinforcement structure can comprise the annular ring structures depicted in FIG. 5-7. In yet other embodiments, the reinforcement structure can comprise different types of structures, such as hexagons, octagons, or shapes or lines that create underlying topography, as depicted in FIG. 11.

In the embodiments shown in FIGS. 3 (and 4), the reinforcement structure comprises an annular ring structure 30 that is surrounded by a dielectric passivation layer 40. The width of the annular ring structure 30 can be configured to be smaller than the exposed area of the chip pad 15 (as shown in FIG. 1). In some configurations, the diameter of the annular ring structure can range from about 20-95% of the diameter of the exposed bond pad.

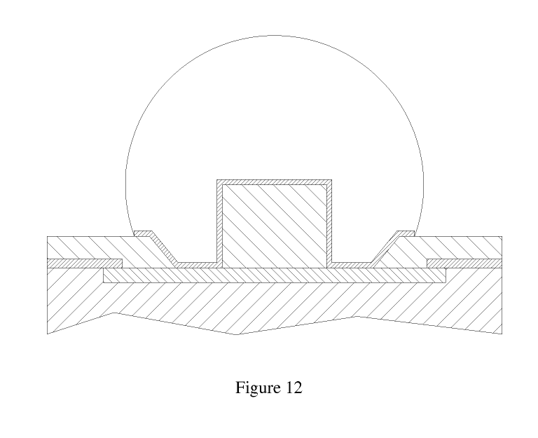

In some embodiments, the annular ring structure 30 comprises non-vertical sidewalls 32 and a substantially planar top 33 that is smaller in diameter than the base 34. The sidewalls 32 of the annular ring structure 30 can slope down to the chip pad 15 and can have any incline that will provide the reinforcing structure and adequate subsequent layer deposition adhesion. In some embodiments, the incline of the sidewalls can range up to about 90 degrees relative to the horizontal plane (i.e., that plane of the upper surface of the substrate 10 or the bond pad 15). In other embodiments, the incline of the sidewalls can range from about 30 to about 80 degrees relative to the horizontal plane. In yet other embodiments, the incline of the sidewalls can range from about 45 to about 70 degrees relative to the horizontal plane. In other configurations, the annular ring structure 30 can comprise substantially vertical sidewalls, resulting in a substantially planar top that is equal in size to the base diameter as shown in FIG. 12.

The annular ring structure 30 is surrounded by a concave region 36 where the dielectric layer 40 has been removed. Thus, the bottom of the concave region contains the chip pad 15 with one side formed from the inclined sidewalls 32 of the annular ring structure and the other side if formed by inclined sidewalls 38 of the passivation dielectric layer 40. The inclined sidewalls 38 can have an incline angle ranging up to about 90 degrees relative to the horizontal plane. In some embodiments, the incline of the sidewalls 38 can range from about 30 to about 70 degrees.

The height of the annular ring structure 30 will depend on thickness of the dielectric layer (or layers) 40 and annular ring material deposition characteristics. In some configurations, relative to the bottom of the concave area 36, the total height of the annular ring structure 30 can be equal to the height of the polymer dielectric layer 40. Thus, the total height for the annular ring structure may range up to about 75 μm. In other embodiments, the total height for the annular ring structure may range from 15 to about 50 μm.

In other embodiments, the height of the annular ring structure 30 need only be higher than the polymer dielectric layer 40. Thus, the height for the annular ring structure relative to the polymer dielectric layer 40 may range up to about 20 μm. In other embodiments, this relative height for the annular ring structure may range from 5 to about 15 μm.

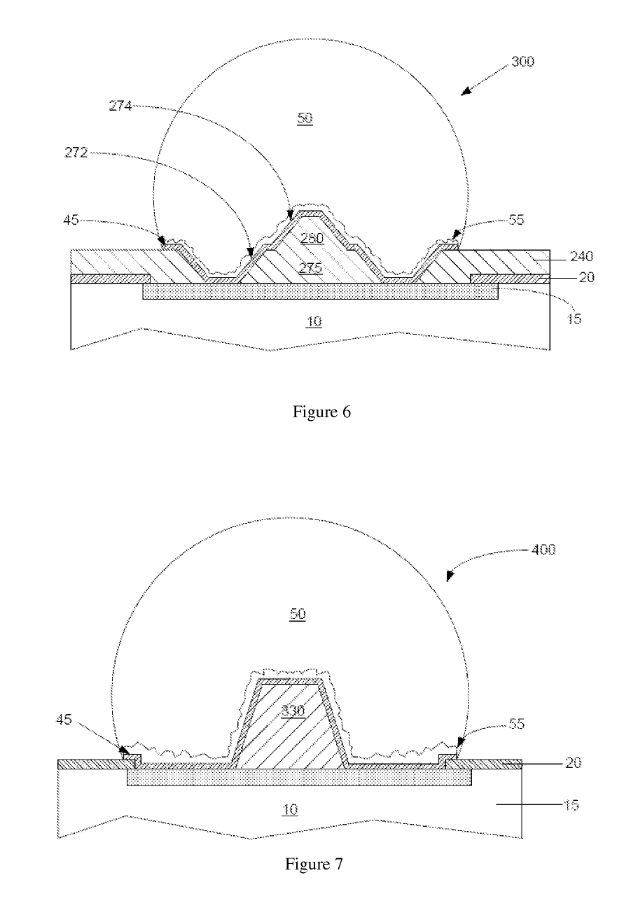

The annular ring structure 30 can be formed using any process that will yield the desired structure. In some embodiments, the annular ring structure 30 can be formed by standard photolithography processes after the surrounding polymer dielectric layer 40 has been applied as depicted in FIGS. 3 (and 4). This process allows the use of alternate materials, if desired, as well as the ability to target a specific annular ring structure 30 height. In the embodiments shown in FIG. 5, an annular ring structure 130 can be formed during the same photolithography process that defines the bond pad openings in the polymer dielectric layer 40. The resulting height of the annular ring structure 130 in these embodiments is about equal to the height of the polymer dielectric layer, as depicted in FIG. 5. In the embodiments shown in FIG. 6, an initial annular ring structure 275 can be formed during the same photolithography process that defines the bond pad openings in the polymer dielectric layer 40, followed by formation of a second annular ring structure 280 on top of the initial annular ring structure 275, as depicted in FIG. 6. This patterning process can be repeated if a higher annular ring structure is desired. In the embodiments shown in FIG. 7, an annular ring structure 330 can be formed by standard photolithography processes without the presence of a surrounding polymer dielectric layer, as depicted in FIG. 7.

After the formation of the annular ring structure 30, the process of manufacturing the WLCSP continues when an under bump metal (UBM) layer 45 is formed. The UBM layer 45 serves as a solderable base layer for the solder ball formed on it later in the manufacturing process, and may act as a diffusion barrier in some cases. The UBM layer 45 can be made of any known conductive material with any known thickness that allows it operate in this manner, including Cu, Ni, Ni(V), or combinations thereof. In some embodiments, the UBM layer 45 comprises a 1-5 μm layer of Ni. In other embodiments, the UBM layer 45 comprises a 1-10 μm layer of Cu.

This UBM layer 45 can be formed using any process known in the art. In some embodiments, the UBM layer can be made by blanket depositing a seed layer (not shown) of the same material as the UBM layer over the annular ring structure 30, concave region 36, and the dielectric layer 40. This seed layer may comprise any known conductive material that can operate as a seed layer, including Ti, TiN, W, Ta, TaN, or combinations thereof. Then, a photoresist (PR) layer can be deposited and patterned using photolithography to form a PR mask that is located over the passivation dielectric layer 40. The UBM layer 45 can then be grown on the exposed portions of the seed layer (in the regions of the annular ring structure 30 and concave region 36) by using the material in the seed layer as an electrical current carrier to attract the additional material that is deposited by electroplating. After the UBM layer 45 is formed, the PR mask can then be removed using any known process. The seed layer with no UBM layer 45 grown on it (which was previously covered by the PR mask) can then be removed using any known process.

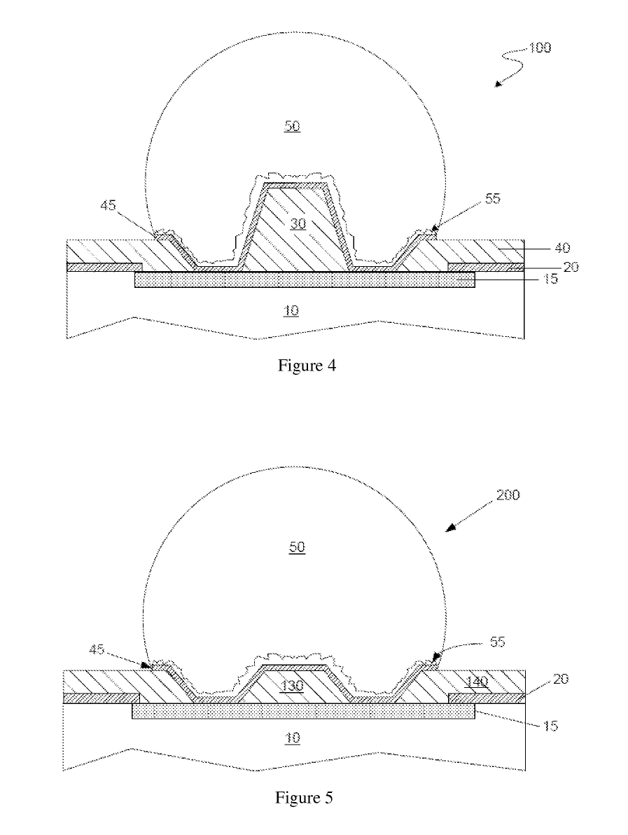

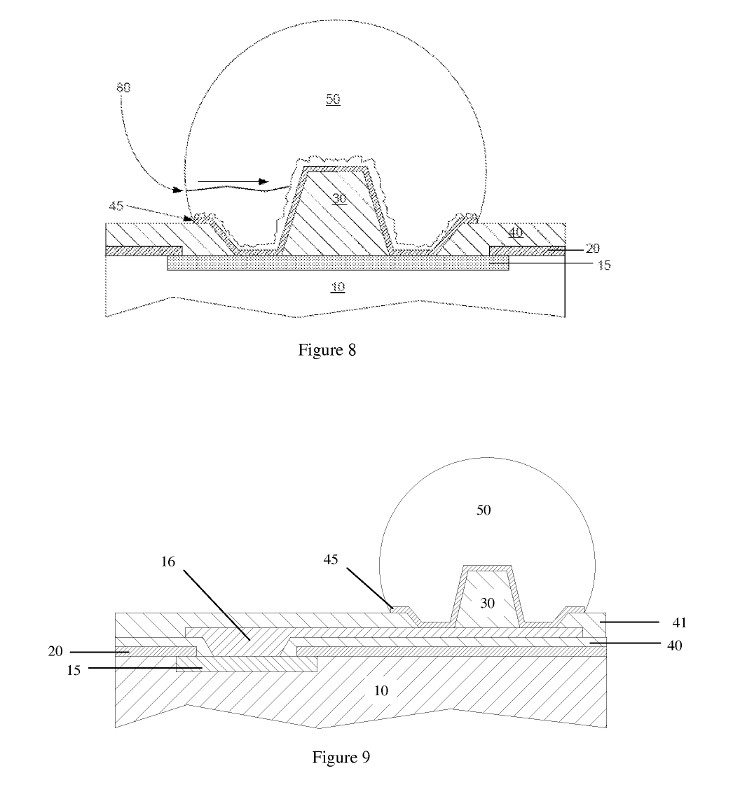

Next, the solder ball 50 can be attached to the resulting structure above the bond pad 15, as shown in FIGS. 3-8. The solder ball (or solder bump) 50 can be formed of any solder material known in the art, including SnPb or SAC solders. The solder ball 50 can be attached to the UBM layer 45 using any process known in the art, including placing the solder ball on the desired area (above chip pad 15) and then re-flowing the solder in the solder ball 50. In other embodiments, the solder ball 50 may be formed by other known methods such as plating, stencil printing, evaporating, or liquid solder transfer. The solder ball 50 accordingly becomes electrically connected to the UBM layer 45 and through it to the chip pad 15. During the reflow process, the metal in the solder ball 50 and the metal in the UBM layer 45 react and form an intermetallic compound 55, as shown in FIGS. 4-8. Because the UMB layer 45 contacts the solder ball 50 with the uneven contact surface created by the annular ring structure 30 and the concave region 35, the contact area of the solder ball 50 has increased, improving the connection reliability between the solder ball 50 and the chip pad 15 in the WLCSP 100 that has been formed.

In some embodiments, the annular reinforcement structure can be configured differently. In these embodiments, the reinforcement structure can be formed as the annular ring structure 130 illustrated in FIG. 5. In these embodiments, the height of the annular ring structure 130 has been configured to match the height of the dielectric passivation layer 140. Thus, the height of the annular ring structure in these embodiments can range from about 5 μm to about 15 μm and the angle of the sidewalls of the annular ring structure 130 can range from about 0 to 90 degrees. Such a configuration for the WLCSP 200 can be formed using the above methods and modifying the patterning process for the dielectric layer 40 that is used to form the annual ring structure 130 and the dielectric passivation layer 140.

In other embodiments, the reinforcement structure can be configured as the annular ring structure illustrated in FIG. 6. In these embodiments, the height of the annular ring structure has been configured to be higher than the height of the dielectric passivation layer 240. Thus, the height of the annular ring structure in these embodiments can range from about 5 μm to about 30 μm. The annular ring structure illustrated in FIG. 6 has been configured with two levels: a first lower level (or base) 275 and a second higher level (or tip) 280. The height of the base 275 can be configured to substantially match the height of the dielectric layer 240. The angle of the sidewalls 272 on the base 275 can be the same or different than the angle of the sidewalls 274 on the tip 280. Thus, the angle of the base sidewalls 272 and the angle of the tip sidewalls 274 can both separately range from 30 to about 90 degrees. Such a configuration for the WLCSP 300 can be formed by modifying the above methods to deposit and pattern a first dielectric material to form dielectric layer 240 and the annular ring base 275, then depositing and patterning a second dielectric material layer on the first dielectric layer to form the annual ring tip 280, which completes the formation of the overall annular ring structure.

In other embodiments, the reinforcement structure can be formed as the annular ring structure 330 illustrated in FIG. 7. In these embodiments, the WLCSP 400 does not contain any surrounding passivation dielectric layer. The height of the annular ring structure 330 in these embodiments can range from 5 to about 75 μm, and the angle of the sidewalls of the annular ring structure 330 can range from 30 to about 90 degrees. Such a configuration for the WLCSP 400 can be formed using standard photolithography techniques.

The annular ring structures described above can be created in the same processing step as the top layer polymer dielectric (i.e. polyimide) if it contains the same material. Where a higher ring structure is needed, it can be made by using multiple dielectric coating steps. The highest ring structure, and best performing in some embodiments, can be obtained by a successive photolithography steps after the initial polymer dielectric deposition or by using a different polymer material that has the ability to be coated and patterned in thick layers.

The WLCSP devices described above contain an annular ring structure near the center of the bond pad. The annular ring structure can comprise a polymeric material that is substantially equal to or greater in height than the top dielectric passivation layer. Where the WLCSP contains no polymer dielectric passivation layer, the annular ring structure can be configured with any suitable height. The annular ring structure can be used to slow the solder crack propagation that can occur. Such cracks 80 often begin near or at the brittle intermetallic compound layer 55 that is formed between the solder ball 50 and the UBM layer 45, which typically results in the failure of the WLCSP. Such a feature which will ultimately increase solder joint reliability in the WLCSP because the crack will either be halted at the annular ring structure, as shown in FIG. 7, or the crack must travel up and over the annular ring structure, essentially increasing the crack failure length

The annular ring structure can also increase the surface area for solder attachment to the UBM layer. This increased surface area can also act to help to improve overall ball shear strength.

The WLCSP devices formed from the methods described above can then be separated from the wafers in which they are formed by sawing along scribe lines that have been formed in the wafer between adjacent WLCSP devices. The individual WLCSP device can then be connected to a printed circuit board (PCB) using the solder balls 50 and used in any electronic device known in the art such as portable computers, disk drives, USB controllers, portable audio devices, or any other portable electronic devices.

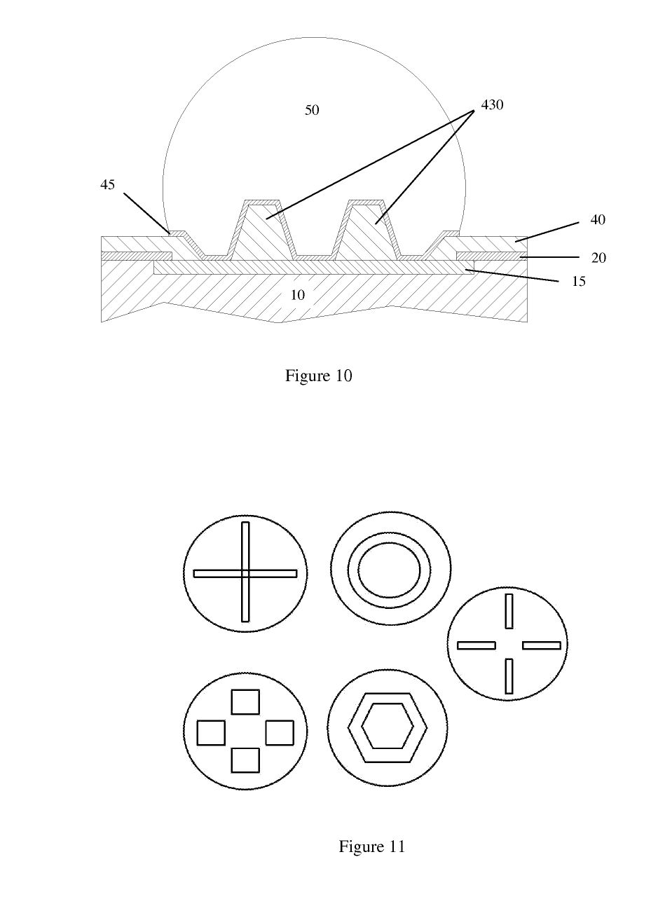

The above WLCSP devices and methods can be modified or altered in several ways. In some configurations, a redistribution layer can be used as known in the art to redistribute the location where the solder ball 50 is formed so that it need not be directly formed over the bond pad 15, as illustrated in FIG. 9 where the UBM layer 45 and annular ring structure 30 are formed over a redistributed bond pad area. A metal redistribution layer 16 comprising Al, Cu, or combinations thereof is formed between a first dielectric re-passivation layer 40 and a second dielectric passivation layer 41. In other variations, multiple annular rings (or a series of rings) 430 inside the bond pad could be defined to improve crack resistance of the solder joint structure, as illustrated in FIG. 10.

In some embodiments, a wafer level chip scale package can be made by the method comprising: providing a substrate containing an integrated circuit with a bond pad formed on an upper surface of the substrate and electrically connected to the integrated circuit; providing a passivation layer formed on an outer portion of the bond pad, leaving an inner portion of the bond pad exposed; providing a dielectric passivation layer located on the passivation layer and a portion of the bond pad not covered by the passivation layer; providing an annular ring structure formed on a part of the inner portion of the bond pad, the annular ring structure having vertical or non-vertical sidewalls, wherein the height of the annular ring structure is greater than or equal to the thickness of dielectric passivation layer; providing a UBM layer covering the annular ring structure and the bond pad; and providing a solder ball attached to the UBM layer.

In other embodiments, a wafer level chip scale package can be made by the method comprising: providing a substrate containing an integrated circuit; forming a bond pad on an upper surface of the substrate that is electrically connected to the integrated circuit; providing a passivation layer formed on an outer portion of the bond pad, leaving an inner portion of the bond pad exposed; depositing a dielectric layer; patterning the dielectric layer to form a dielectric passivation layer covering a portion of the bond pad not covered by the passivation layer, wherein the patterning process forms an annular ring structure on a part of the inner portion of the bond pad, the annular ring structure having vertical or non-vertical sidewalls, wherein the height of the annular ring structure is greater than or equal to the thickness of dielectric passivation layer; forming a UBM layer to cover the annular ring structure and the bond pad; and attaching a solder ball to the UBM layer.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A wafer level chip scale package, comprising:
a substrate containing an integrated circuit with a bond pad formed on an upper surface of the substrate and electrically connected to the integrated circuit;
a passivation layer formed on an outer portion of the bond pad, leaving an inner portion of the bond pad exposed;
an annular ring structure formed on a part of the inner portion of the bond pad, the annular ring structure having sidewalls and being formed of a polymeric dielectric material;
a UBM layer covering the annular ring structure and the bond pad; and
a solder ball attached to the UBM layer.

2. The package of claim 1, wherein the sidewalls of the annular ring structure have an incline relative to the plane of the bond pad ranging up to less than 90 degrees.

3. The package of claim 2, wherein the sidewalls of the annular ring structure have an incline ranging from about 30 to 80 degrees.

4. The package of claim 1, wherein the height of the annular ring structure relative to the bond pad ranges up to about 75 μm.

5. The package of claim 1, wherein the sidewalls of the annular ring structure are substantially vertical.

6. The package of claim 1, further comprising a dielectric passivation layer located on the passivation layer and a portion of the bond pad not covered by the passivation layer

7. The package of claim 6, herein the height of the annular ring structure is substantially the same as or greater than the thickness of dielectric passivation layer by up to about 20 μm.

8. The package of claim 6, wherein the annular ring structure comprises the same material as the dielectric passivation layer.

9. The package of claim 8, wherein the material comprises a polymeric dielectric material including polyimide, benzocyclobutene, or polybenzoxazole.

10. A wafer level chip scale package, comprising:
a substrate containing an integrated circuit with a bond pad formed on an upper surface of the substrate and electrically connected to the integrated circuit;
a passivation layer formed on an outer portion of the bond pad, leaving an inner portion of the bond pad exposed;
a dielectric passivation layer located on the passivation layer and a portion of the bond pad not covered by the passivation layer.
an annular ring structure formed on a part of the inner portion of the bond pad, the annular ring structure having non-vertical sidewalls, wherein the height of the annular ring structure is greater than the thickness of dielectric passivation layer;
a UBM layer covering the annular ring structure and the bond pad; and
a solder ball attached to the UBM layer.

11. The package of claim 10, wherein the sidewalls of the annular ring structure have an incline relative to the plane of the bond pad ranging up to less than 90 degrees.

12. The package of claim 11, wherein the sidewalls of the annular ring structure have an incline ranging from about 30 to 80 degrees.

13. The package of claim 10, wherein the height of the annular ring structure relative to the bond pad ranges up to about 75 μm.

14. The package of claim 13, wherein the height of the annular ring structure is greater than the height of the dielectric passivation layer by up to about 20 μm.

15. The package of claim 10, wherein the annular ring structure comprises the same material as the dielectric passivation layer.

16. The package of claim 15, wherein the material comprises a polymeric dielectric material including polyimides, benzocyclobutene, or polybenzoxazole.

17. The package of claim 10, wherein the annular ring structure comprises a different material than the dielectric passivation layer.

18. An electronic apparatus, comprising:
a printed circuit board; and
a wafer level chip scale package attached to the printed circuit board and comprising:
a substrate containing an integrated circuit with a bond pad formed on an upper surface of the substrate and electrically connected to the integrated circuit;
a passivation layer formed on an outer portion of the bond pad, leaving an inner portion of the bond pad exposed;
a dielectric passivation layer located on the passivation layer and a portion of the bond pad not covered by the passivation layer.
an annular ring structure formed on a part of the inner portion of the bond pad, the annular ring structure having vertical or non-vertical sidewalls, wherein the height of the annular ring structure is greater than the thickness of dielectric passivation layer;
a UBM layer covering the annular ring structure and the bond pad; and
a solder ball attached to the UBM layer.

19. The package of claim 18, wherein the sidewalls of the annular ring structure have an incline relative to the plane of the bond pad ranging up to less than 90 degrees.

20. The package of claim 19, wherein the sidewalls of the annular ring structure have an incline ranging from about 30 to 80 degrees.

21. The package of claim 18, wherein the height of the annular ring structure relative to the bond pad ranges up to about 75 μm.

22. The package of claim 18, wherein the height of the annular ring structure is greater than the height of the dielectric passivation layer by up to about 20 μm.

23. The apparatus of claim 18, wherein the annular ring structure comprises the same material as the dielectric passivation layer.

24. The apparatus of claim 18, wherein the annular ring structure comprises a different material than the dielectric passivation layer.
